(19) United States
(12) Patent Application Publication
(10) Pub. No.: US 2025/0331382 A1
(43) Pub. Date: Oct. 23, 2025

(54) DISPLAY DEVICE AND ELECTRONIC APPARATUS INCLUDING THE SAME

(71) Applicant: Samsung Display Co., Ltd., Yongin-Si (KR)

(72) Inventors: TAE-HO KIM, Yongin-si (KR); JAEWOO LEE, Yongin-si (KR); SEUNG-JUN LEE, Yongin-si (KR); SANG MIN JEON, Yongin-si (KR)

(21) Appl. No.: 19/000,738

(22) Filed: Dec. 24, 2024

(30) Foreign Application Priority Data
Apr. 19, 2024 (KR) 10-2024-0052498

(51) Int. Cl. H10K 59/131

(52) U.S. Cl. CPC H10K 59/1315

(57) ABSTRACT

A display device is disclosed that includes a substrate including a display area, a first peripheral area positioned in a direction away from the display area, an integrated circuit area spaced apart from the first peripheral area where a data driver is disposed, and a bendable area positioned between the first peripheral and integrated circuit areas. A data distributor is positioned between the integrated circuit and bendable areas. First and second data connection line groups are electrically connected to the data distributor and output different signals from the data driver in response to different distribution selection signals. Conductor lines are positioned between the first and second data connection line groups. A fourth power line is disposed on a different layer from the first and second data connection line groups and is electrically connected to the conductor lines to provide a first power voltage to the conductor lines.

### CROSS-REFERENCE TO RELATED APPLICATION(S)

This application claims priority under 35 USC § 119 to Korean Patent Application No. 10-2024-0052498 filed on Apr. 19, 2024, in the Korean Intellectual Property Office (KIPO), the entire disclosure of which is incorporated by reference herein.

### BACKGROUND

### 1. Field

Embodiments relate to a display device. More specifically, embodiments relate to a display device and an electronic apparatus including the same that prevents coupling and minimizes line resistance.

### 2. Description of the Related Art

As information technology develops, the importance of display devices providing a connection medium between users and information is being highlighted. For example, the use of display devices such as liquid crystal display devices (LCD), organic light emitting display devices (OLED), plasma display devices (PDP), and quantum dot display devices is increasing.

Generally, a display device includes a display panel and a driver. The display panel includes a plurality of gate lines, a plurality of data lines, and a plurality of pixels. The display panel displays an image based on input image data. The driver includes a gate driver, a data driver, and a controller. The gate driver outputs gate signals to the gate lines. The data driver outputs data signals to the data lines. The controller controls the gate driver and the data driver.

The driver may include a demux circuit. The demux circuit may branch first light-emit data and second light-emit data.

The demux circuit may be disposed adjacent to an integrated circuit included as a data driver or part of a data driver. In this case, the display device in which the demux circuit is disposed adjacent to the integrated circuit may have a greater number of lines floating on the display panel than a display device in which the demux circuit is disposed adjacent to the display panel.

### SUMMARY

Embodiments of the disclosure provide a display device with reduced dead space and improved reliability.

Embodiments of the disclosure provide an electronic apparatus including the display device.

A display device according to an embodiment includes: a substrate including a display area and a peripheral area, the peripheral area including a first peripheral area positioned in a direction away from the display area, an integrated circuit area spaced apart in the direction from the first peripheral area, and a bendable area positioned between the first peripheral area and the integrated circuit area, a data driver disposed in the integrated circuit area on the substrate, a data distributor positioned between the integrated circuit area and the bendable area on the substrate, first data connection line groups electrically connected to the data distributor and configured to receive a first data signal output from the data driver in response to a first distribution selection signal, second data connection line groups electrically connected to the data distributor and configured to receive a second data signal output from the data driver in response to a second distribution selection signal, conductor lines positioned between the first data connection line groups and the second data connection line groups, and a fourth power line disposed on a different layer from the first data connection line groups and the second data connection line groups in a cross-sectional view and electrically connected to the conductor lines through a contact hole to provide a first power voltage to the conductor lines.

In an embodiment, the first data connection line groups, the second data connection line groups, and the conductor lines may be positioned on a same layer.

In an embodiment, the display device may further include a first insulating layer disposed on the substrate, a second insulating layer disposed on first insulating layer, a third insulating layer disposed on the second insulating layer, a fourth insulating layer disposed on the third insulating layer, and a fifth insulating layer disposed on the fourth insulating layer, and the first data connection line groups, the second data connection line groups, and the conductor lines may be covered by the fourth insulating layer, and the fourth power line may be covered by the fifth insulating layer.

In an embodiment, a width of the fourth power line may be greater than a width of each of the conductor lines, in the cross-sectional view.

In an embodiment, the display device may further include an additional power line electrically connected to the conductor lines through a contact hole in a layer different from the fourth insulating layer and the fifth insulating layer, in the cross-sectional view.

In an embodiment, a width of the additional power line may be greater than a width of each of the conductor lines.

In an embodiment, the additional power line may include a first power line covered by the first insulating layer, and a second power line covered by the second insulating layer, and electrically connected to the first power line and the conductor lines through a contact hole.

In an embodiment, the display device may further include a sixth insulating layer disposed on the fifth insulating layer, and a fifth power line covered by the sixth insulating layer.

In an embodiment, the additional power line may include a first power line covered by the first insulating layer, and electrically connected to the conductor lines through a contact hole.

In an embodiment, the additional power line may include a second power line covered by the second insulating layer, and electrically connected to the conductor lines through a contact hole.

In an embodiment, the additional power line may include a third power line covered by the third insulating layer, and electrically connected to the conductor lines through a contact hole.

In an embodiment, the additional power line may include a second power line covered by the second insulating layer, and a third power line covered by the third insulating layer, and electrically connected to the second power line and the conductor lines through a contact hole.

In an embodiment, the additional power line may include a first power line covered by the first insulating layer, and a third power line covered by the third insulating layer, and electrically connected to the first power line and the conductor lines through a contact hole.

In an embodiment, in the cross-sectional view, the additional power line disposed under the fourth insulating layer may include a first metal, and the additional power line disposed on the fourth insulating layer may include a second metal different from the first metal.

In an embodiment, a resistivity of the second metal may be smaller than a resistivity of the first metal.

In an embodiment, the first data connection line groups, the second data connection line groups, and the conductor lines may be spaced apart from each other in a direction crossing the one direction, in the cross-sectional view.

In an embodiment, a bending line on which the substrate may be folded is defined in the bendable area, and when viewed from a side, with the substrate folded along the bending line, a pixel may be disposed in the display area on the substrate, and the data distributor and the data driver may be positioned under the substrate.

A display device according to an embodiment includes: a substrate including a display area and a peripheral area, the peripheral area including a first peripheral area positioned in a direction away from the display area, an integrated circuit area spaced apart from the first peripheral area, and a bendable area positioned between the first peripheral area and the integrated circuit area, a data driver disposed in the integrated circuit area on the substrate, a data distributor positioned between the integrated circuit area and the bendable area on the substrate, first data connection line groups electrically connected to the data distributor and configured to receive a first data signal output from the data driver in response to a first distribution selection signal, second data connection line groups electrically connected to the data distributor and configured to receive a second data signal output from the data driver in response to a second distribution selection signal, conductor lines positioned between the first data connection line groups and the second data connection line groups, and configured to receive a first power voltage, and a fourth power line disposed on the first data connection line groups and the second data connection line groups in a cross-sectional view, and having a width greater than a width of each of the conductor lines.

In an embodiment, the display device may further include an additional power line disposed under the conductor lines in the cross-sectional view, and electrically connected to the conductor lines through a contact hole.

In an embodiment, the display device may further include an additional power line disposed on the fourth power line in the cross-sectional view, and electrically connected to the conductor lines through a contact hole.

An electronic apparatus according to an embodiment includes: a power module which supplies power and a display device which provides the power. The display device includes: a substrate including a display area and a peripheral area, the peripheral area including a first peripheral area positioned in a direction away from the display area, an integrated circuit area spaced apart from the first peripheral area, and a bendable area positioned between the first peripheral area and the integrated circuit area, a data driver disposed in the integrated circuit area on the substrate, a data distributor positioned between the integrated circuit area and the bendable area on the substrate, first data connection line groups electrically connected to the data distributor and configured to receive a first data signal output from the data driver in response to a first distribution selection signal, second data connection line groups electrically connected to the data distributor and configured to receive a second data signal output from the data driver in response to a second distribution selection signal, conductor lines positioned between the first data connection line groups and the second data connection line groups, and configured to receive a first power voltage, and a fourth power line disposed on the first data connection line groups and the second data connection line groups in a cross-sectional view, and having a width greater than a width of each of the conductor lines.

In an embodiment, the display device may further include an additional power line disposed under the conductor lines in the cross-sectional view, and electrically connected to the conductor lines through a contact hole.

In an embodiment, the display device may further include an additional power line disposed on the fourth power line in the cross-sectional view, and electrically connected to the conductor lines through a contact hole.

In a display device and an electronic apparatus according to an embodiment, the conductor lines may be disposed between the data connection line groups branched from the data distributor at the bottom of the bendable area of the display panel, and the additional power line may be disposed in the conductor lines that contacts the power line having a large area. Accordingly, coupling between output signals may be prevented and the increase in resistance of the power line may be minimized.

In addition, the additional power line may be disposed above or below the conductor lines. Accordingly, the coupling between the output signals may be prevented and the increase in resistance of the power line may be minimized.

In addition, the resistivity of the metal material included in the additional power line disposed on the conductor line may be smaller than the resistivity of the metal material included in the additional power line disposed below the conductor line. Accordingly, the increase in resistance of the power line may be further minimized.

However, the effect of the disclosure is not limited to the aforementioned effect, and it may be expanded in various ways to the extent that it does not deviate from the idea and domain of the disclosure.

### BRIEF DESCRIPTION OF THE DRAWINGS

FIG. 1 is a block diagram illustrating a display device according to an embodiment.

FIG. 2 is a plan view illustrating an embodiment of a display panel and a data driver of FIG. 1.

FIG. 3 is a view illustrating an embodiment of a second peripheral area of FIG. 2.

FIG. 4 is a circuit diagram illustrating an embodiment of a pixel included in the display device of FIG. 1.

FIG. 5 is a timing diagram illustrating an example in which the coupling occurs in a demux switching structure.

FIGS. 6, 7, 8, 9, 10, 11, and 12 are views illustrating embodiments of a conductor line and a power line.

FIG. 13 is a block diagram illustrating an electronic apparatus according to an embodiment.

FIG. 14 is a diagram illustrating an example in which the electronic apparatus of FIG. 13 is implemented as a smart phone.

FIG. 15 is a view illustrating an embodiment of a bending state of the smartphone of FIG. 14.

FIG. 16 is a block diagram illustrating an electronic apparatus according to an embodiment.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

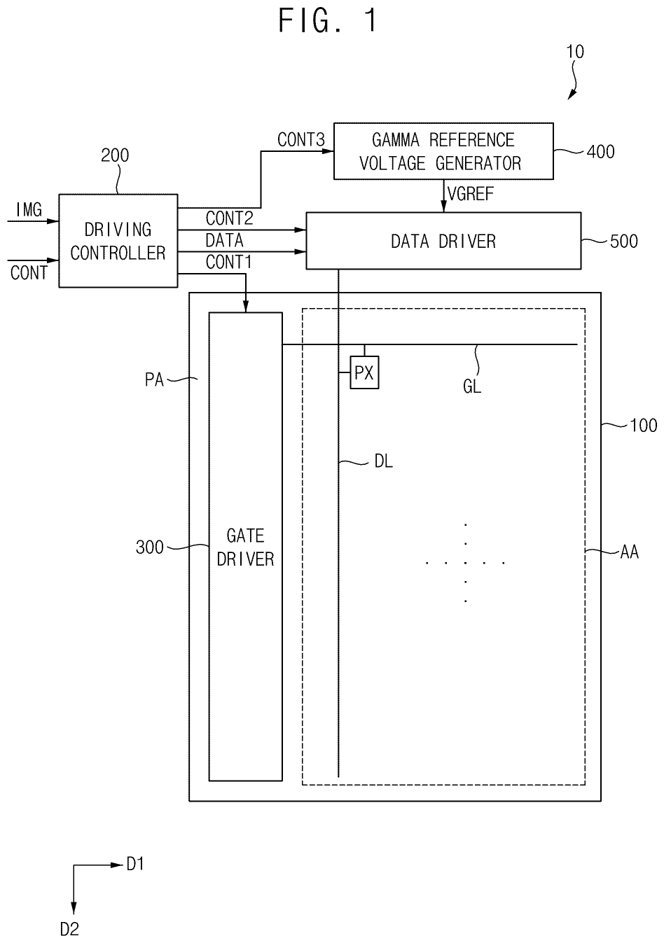

FIG. 1 is a block diagram illustrating a display device according to an embodiment of the disclosure.

Referring to FIG. 1, the display device may include a display panel 100 and a display panel driver.

The display panel 100 may include pixels PX, gate lines GL, and data lines DL.

In display panel 100, a display area AA and a peripheral area PA may be defined.

The pixels PX may be disposed in the display area AA. For example, the pixels PX may be a plurality. The plurality of pixels PX may be disposed repeatedly along a first direction D1 and a second direction D2. For example, the first direction D1 and the second direction D2 may cross each other. For example, the first direction D1 may be perpendicular to the second direction D2.

The peripheral area PA may be adjacent to the display area AA. For example, the peripheral area PA may surround the display area AA. In the peripheral area PA, various components (e.g., drive chips, or the like) may be disposed to drive the pixels PX.

However, the disclosure is not limited thereto. For example, the image may also be displayed in the peripheral area PA.

Each of the gate lines GL and the data lines DL may be electrically connected to the pixels PX. For example, the gate line GL may extend in the first direction D1. The data line DL may extend in the second direction D2.

The pixel PX may receive a gate signal via the gate line GL. In addition, the pixel PX may receive a data signal via the data line DL. The pixel PX may be filled with the data signal in response to the gate signal.

In an embodiment, the image may be displayed in a direction perpendicular to a display surface (e.g., a plane defined by the first direction D1 and the second direction D2). However, the disclosure is not limited thereto. For example, the image may be displayed as a side, a back, or the like of the display panel 100.

The display panel driver may include a driving controller 200, a gate controller 300, a gamma reference voltage generator 400, and a data driver 500.

In an embodiment, the driving controller 200 and the data driver 500 may be integrally formed. For example, a driving module including at least the driving controller 200 and the data driver 500 which are integrally formed may be called to a timing controller embedded data driver (“TED”).

In an embodiment, the driving controller 200, the gamma reference voltage generator 400, and the data driver 500 may be integrally formed.

The driving controller 200 may receive input image data IMG and an input control signal CONT from an external apparatus.

In an embodiment, the input image data IMG may include red image data, green image data and blue image data. However, the disclosure is not limited thereto. For example, the input image data IMG may include white image data. For example, the input image data IMG may include magenta image data, yellow image data and cyan image data.

In an embodiment, the input control signal CONT may include a master clock signal and a data enable signal. However, the disclosure is not thereto. For example, the input control signal CONT may further include a vertical synchronizing signal, a horizontal synchronizing signal, or the like.

The driving controller 200 mat generate a first control signal CONT1, a second control signal CONT2, a third control signal CONT3, and a data signal DATA based on the input image data IMG and the input control signal CONT.

The driving controller 200 may generate the first control signal CONT1 for controlling an operation of the gate driver 300 based on the input control signal CONT, and output the first control signal CONT1 to the gate driver 300. The first control signal CONT1 may further include a vertical start signal and a gate clock signal.

The driving controller 200 may generate the second control signal CONT2 for controlling an operation of the data driver 500 based on the input control signal CONT, and output the second control signal CONT2 to the data driver 500. The second control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the third control signal CONT3 for controlling an operation of the gamma reference voltage generator 400 based on the input control signal CONT, and output the third control signal CONT3 to the gamma reference voltage generator 400.

The gate driver 300 may generate gate signals driving the gate lines GL in response to the first control signal CONTI received from the driving controller 200. The gate driver 300 may output the gate signals to the gate lines GL.

In an embodiment, the gate driver 300 may be disposed in the peripheral area. For example, the gate driver may be mounted on the peripheral area. However, the disclosure is not limited thereto. For example, the gate driver 300 may be integrated on the peripheral area of the display panel 100.

The gamma reference voltage generator 400 may generate a gamma reference voltage VGREF in response to the third control signal CONT3 received from the driving controller 200. The gamma reference voltage generator 400 may provide the gamma reference voltage VGREF to the data driver 500. The gamma reference voltage VGREF may have a value corresponding to a level of the data signal DATA.

In an embodiment, the gamma reference voltage generator 400 may be disposed in the driving controller 200. However, the disclosure is not limited thereto. For example, the gamma reference voltage generator 400 may be disposed in the data driver 500.

The data driver 500 may receive the second control signal CONT2 and the data signal DATA from the driving controller 200. In addition, the data driver 500 may receive the gamma reference voltages VGREF from the gamma reference voltage generator 400. The data driver 500 may convert the data signal DATA into data voltages having an analog type using the gamma reference voltages VGREF. The data driver 500 may output the data voltages to the data lines DL.

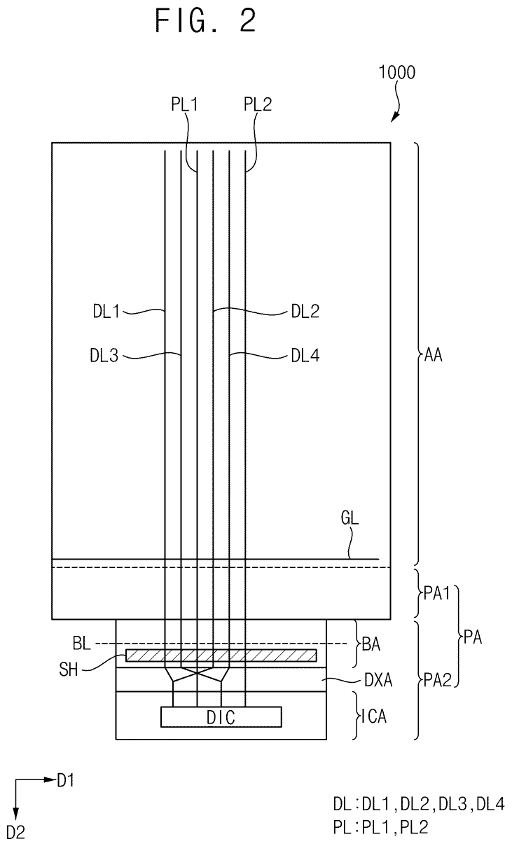

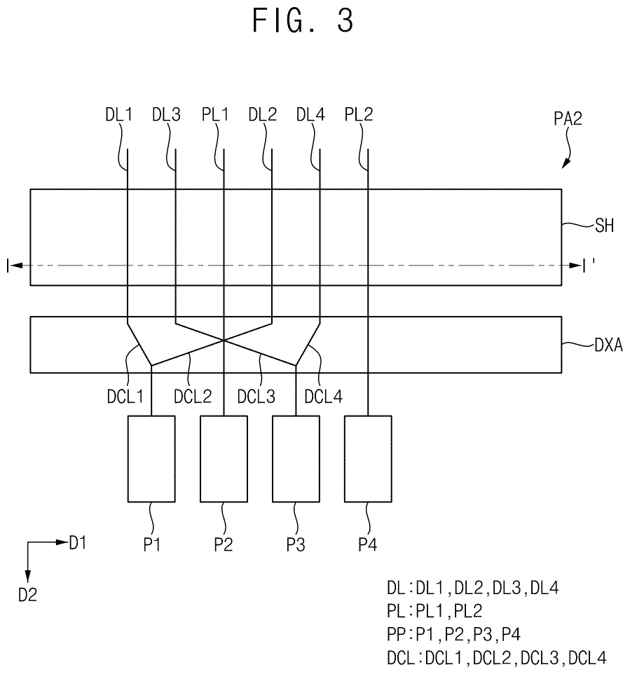

FIG. 2 is a plan view illustrating an embodiment of the display panel and the data driver of FIG. 1. FIG. 3 is a view illustrating an embodiment of the second peripheral area of FIG. 2.

Referring to FIGS. 1, 2, and 3, a display device 1000 according to embodiments of the disclosure may include the display panel 100, the data driver 500, and a data distributor.

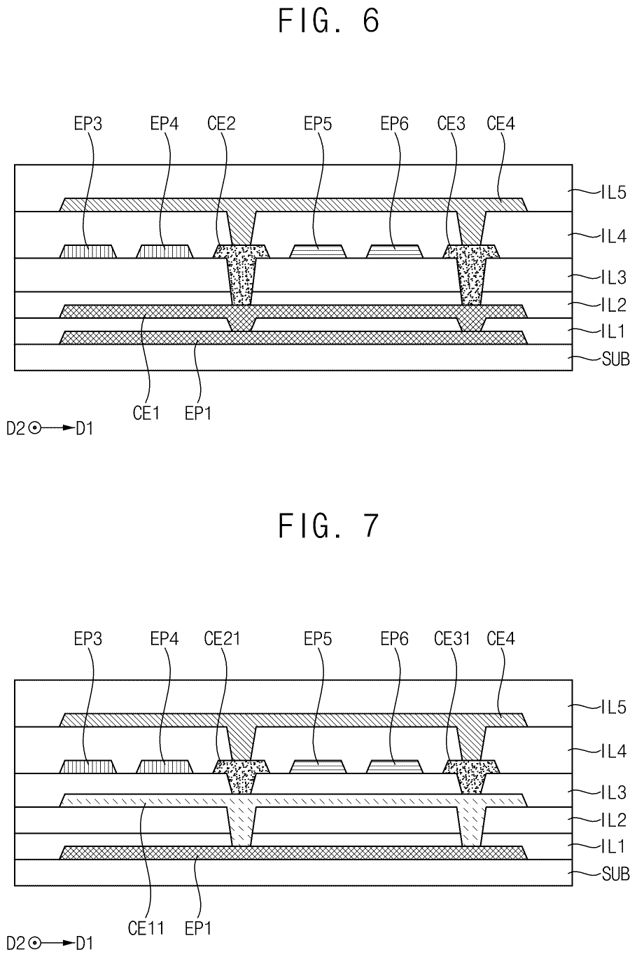

As described above, the display panel 100 may include the display area AA and the peripheral area PA. Correspondingly, the display panel 100 may include a substrate (e.g., a substrate SUB of FIGS. 6, 7, 8, 9, 10, 11, and 12).

In an embodiment, the display area AA may have a rectangular shape in a plan view, and edges of the display area AA may be rounded and curved, however, the disclosure is not limited thereto.

In an embodiment, in the display area AA, the pixels PX may be disposed. The pixels PX may include a plurality of sub-pixels.

In an embodiment, each of the plurality of sub-pixels may emit different color-light. For example, each of the plurality of sub-pixels may include a first sub-pixel, a second sub-pixel, and a third sub-pixel. The first sub-pixel may emit the red light. The second sub-pixel may emit the green light. The third sub-pixel may emit the blue light.

However, the disclosure is not limited thereto. For example, each of the plurality of sub-pixels may emit a same color-light, each of the plurality of sub-pixels may emit the white light, or a type of color-light emitted by each of the plurality of sub-pixels may vary.

In an embodiment, the peripheral area PA may be adjacent to the display area AA. In an embodiment, the peripheral area PA may include a first peripheral area PA1 and a second peripheral area PA2. The first peripheral area PA1 may be positioned in a direction (e.g., the second direction D2) from the display area AA. The second peripheral area PA2 may be positioned in the direction from the first peripheral area PA1.

In an embodiment, the second peripheral area PA2 may include a bendable area BA and an integrated circuit area ICA.

In an embodiment, the bendable area BA may be positioned between the first peripheral area PA1 and the integrated circuit area ICA.

In an embodiment, a bend line BL that folds to a back surface of the display panel 100 may be defined in the bendable area BA. The bendable area BA may be a portion where the display panel 100 folds. For example, the back surface of the display panel 100 may be opposite to the display surface of the display panel 100. For example, the back surface and the display surface may be opposite each other in the direction in which the image is displayed.

In an embodiment, a data distributor DXA may be positioned between the integrated circuit area ICA and the bendable area BA.

In an embodiment, the data distributor DXA may include mux circuits. The mux circuits may be disposed along the first direction D1.

In an embodiment, the data distributor DXA may be plural. For example, the plurality of data distributors DXA may be spaced apart from each other along the first direction D1. However, the disclosure is not limited thereto. There may be one DXA.

In a case of a display device according to a comparative embodiment, the data distributor DXA may be positioned adjacent to the display surface of the display panel 100. For example, the data distributor DXA may be disposed in the first peripheral area PA1. In this case, in the case of the display device according to the comparative embodiment, dead space (i.e., area where the image is not displayed) may be as large as a size of the data distributor DXA.

However, the display device 1000 according to embodiments of the disclosure may have the data distributor DXA positioned on the back surface of the display panel 100 (e.g., between a data drive chip DIC and the bending area BA).

In an embodiment, in a side view, in a state where the display panel 100 is folded along the bending line BL (i.e., in the bending state), the data driver 500 (e.g., the data drive chip DIC) and the data distributor DXA may be positioned on the back of the display panel 100.

That is, in the bending state, the data distributor DXA included in the display panel 100 may overlap on the plane (e.g., the plane defined by the first direction D1 and the second direction D2) with the first peripheral area PA1 or the display area AA. Thus, the dead space of the display device 1000 according to embodiments of the disclosure may be reduced.

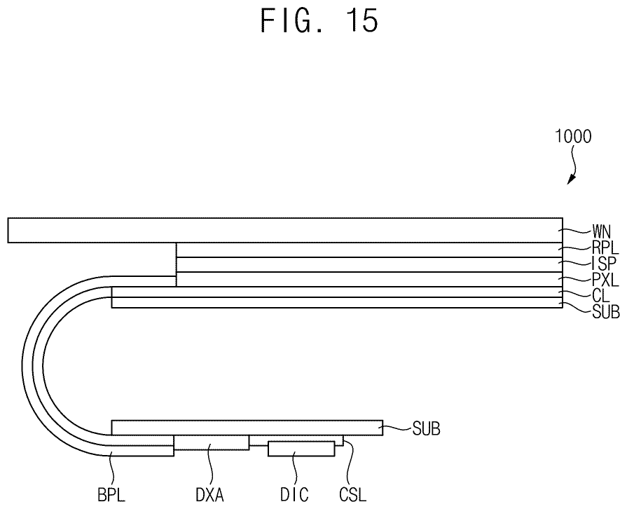

A detailed description of the display panel 100 in the bent state along the bending line BL will be described below in reference to FIG. 15.

In an embodiment, the integrated circuit area ICA may be spaced in one direction (e.g., in the second direction D2) from the first peripheral area PA1.

In an embodiment, the data driver 500 may be disposed in the integrated circuit area ICA. For example, the data driver 500 may be formed in a form of the data driving chip DIC.

In the FIGS. 1, 2, and 3, the data line DL may include a longitudinal line (e.g., a type of line extended in a direction parallel to the second direction D2), however, the disclosure is not limited thereto. For example, the display panel 100 may further include a transverse line (e.g. a type of line extended in a direction parallel to the first direction D1). The data voltage may be transmitted to the pixels PX via the longitudinal line electrically connected to the transverse line.

The display device 10000 described above is illustrative, and the components included in the display device 1000 may be omitted, or additional components may further include.

In an embodiment, the display device 1000 may further include a light-emit driver, a light-emit control line, a spider line, a data transfer line, or the like.

In an embodiment, the light-emit driver may generate a light-emit control signal that controls luminance.

In an embodiment, the light-emit control line may provide the light-emit control signal to the pixel PX.

In an embodiment, the spider line may connect the data driver 500 and the data distributor DXA.

In an embodiment, the data transfer line may connect the data line DL and the data distributor DXA. For example, the data transfer line may include a data fan-out line connecting to the data line DL in the first peripheral area PA1, a data bending line connecting to the data fan-out line in the bendable area BA, and a data connection line connecting to the data bending line in the data distributor DXA (e.g., a first data connection line DCL1, a second data connection line DCL2, a third data connection line DCL3, and a fourth data connection line DCL4 of FIG. 3).

In an embodiment, as shown in FIG. 3, the display device 1000 of FIG. 2 may include data connection line groups DCL. For example, data connection line groups DCL may include first data connection line groups and second data connection line groups. For example, the first data connection line groups may include the first data connection line DCL1 and the second data connection line DCL2. The second data connection line groups may include the third data connection line DCL3 and the fourth data connection line DCL4.

In an embodiment, the first data connection line groups may be electrically connected to the data distributor DXA and may receive the output data signal from the data driver 500 (e.g., the data drive chip DIC) in response to a first distribution selection signal.

In an embodiment, the second data connection line groups may be electrically connected to the data distributor DXA and may receive the output data signal from the data driver 500 (e.g., the data drive chip DIC) in response to a second distribution selection signal.

In an embodiment, in a cross-sectional view, the first data connection line groups, the second data connection line groups, and the conductor lines may be spaced apart from each other in a direction crossing the one direction. In an embodiment, conductor lines PL may be disposed between the first data connection line groups and the second data connection line groups. Accordingly, the data connection line groups may be grouped.

In an embodiment, the first data connection line groups (e.g., the first data connection line DCL1 and the second data connection line DCL2) may be adjacent to each other. The second data connection line groups (e.g., the third data connection line DCL3 and the fourth data connection line DCL4) may be adjacent to each other. The first data connection line groups and the second data connection line groups may be spaced apart by the conductor lines (e.g., a first conductor line PL1). That is, the first data connection line groups, the conductor lines PL, and the second data connection line groups may be disposed sequentially and repeatedly along the first direction D1.

However, the disclosure is not limited thereto. For example, the number of lines included in the data connection line groups (e.g., the first data connection line groups and the second data connection line groups respectively), the number of conductor lines PL positioned between the first data connection line groups and the second data connection line groups, or the like, may vary variously. For example, each of the first data connection line groups and the second data connection line groups positioned on both sides of the first conductor line PL1 may include four data connection lines.

In an embodiment, the pads may include a first pad P1, a second pad P2, a third pad P3, and a fourth pad P4.

In an embodiment, each of the pads may be connected with two groups of data connection line groups. Accordingly, each of the pads may selectively (alternately) provide the data signals to the two groups of data connection line groups. However, the disclosure is not limited thereto.

In an embodiment, the first data connection line DCL1 and the second data connection line DCL2 may branch from the first pad P1. The first data connection line DCL1 may be connected to the first data line DL1. The first data line DL1 may be supplied with the data signal in response to the first distribution selection signal. The second data connection line DCL2 may be connected to the second data line DL2. The second data line DL2 may be supplied the data signal in response to the second distribution selection signal.

The third data connection line DCL3 and the fourth data connection line DCL4 may branch from the third pad P3. The third data connection line DCL3 may be connected to the third data line DL3. The third data line DL3 may be supplied the data signal in response to the first distribution selection signal. The fourth data connection line DCL4 may be connected to the fourth data line DL4. The fourth data line DL4 may be supplied the data signal in response to the second distribution selection signal.

In an embodiment, the conductor lines PL may be disposed on the substrate and each of the conductor line may be positioned between one of the first data connection line groups and one of the second data connection line groups. In an embodiment, each of the conductor lines PL may be supplied a first power voltage.

In an embodiment, the conductor lines PL may include the first conductor line PL1 and a second conductor line PL2.

In an embodiment, the first conductor line PL1 may receive the first power voltage (e.g., “ELVDD”) from a first power pad (e.g., the second pad P2). The first power voltage may be provided to the pixels PX via the first conductor line PL1.

In an embodiment, the second conductor line PL2 may receive the first power voltage from a second power pad (e.g., the fourth pad P4). The first power voltage may be provided to the pixels PX via the second conductor line PL2.

In an embodiment, the first conductor line PL1 and the second conductor line PL2 may be spaced from each other in the first direction D1 and extended in the second direction D2.

In an embodiment, the conductor lines PL may receive a second power supply voltage (e.g., “ELVSS”) from the power pad (e.g., the first power pad or the second power pad). The second supply voltage may be provided to the pixels PX via conductor lines PL.

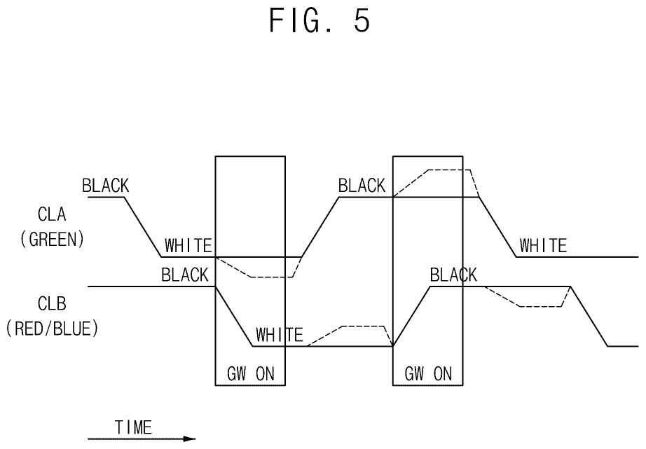

As each of the conductor lines PL are positioned between one of the first data connection line groups and one of the second data connection line groups, an occurrence of coupling between the first data connection line groups and the second data connection line groups (e.g., see FIG. 5) may be prevented.

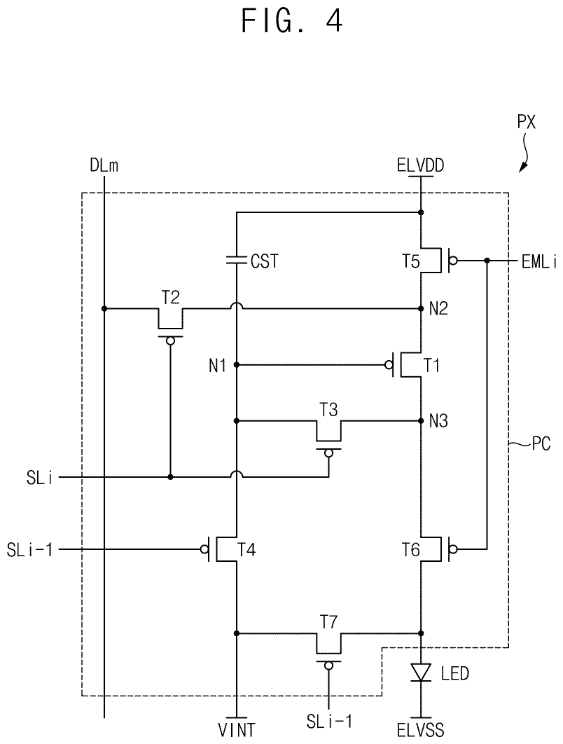

FIG. 4 is a circuit diagram illustrating an embodiment of the pixel included in the display device of FIG. 1.

Each of the pixels PX may include a pixel circuit PC and a light emitting element LED. The pixel circuits PC may have substantially the same structure. Hereinafter, a pixel PX connected to a m-th data line DLm and a i-th scan line SLi (the gate line) will be described.

Referring to FIG. 4, for example, the pixel circuit PC may include first to seventh pixel transistors T1, T2, T3, T4, T5, T6, and T7, and a storage capacitor CST.

The first pixel transistor Tl may include a gate electrode connected to a first node N1, a first electrode connected to a second node N2, and a second electrode connected to a third node N3.

The second pixel transistor T2 may include a gate electrode connected to the i-th scan line SLi, a first electrode connected to the m-th data line DLm, and a second electrode connected to the second node N2.

The third pixel transistor T3 may include a gate electrode connected to the i-th scan line SLi, a first electrode connected to the first node N1, and a second electrode connected to the third node N3.

The fourth pixel transistor T4 may include a gate electrode connected to a i-1th scan line SLi-1, a first electrode to which an initialization signal VINT is applied, and a second electrode connected to the first node N1.

The fifth pixel transistor T5 may include a gate electrode connected to a i-th emission control line EMLi, a first electrode to which a first power voltage ELVDD is applied, and a second electrode connected to the second node N2. The first power voltage ELVDD may be a high power supply voltage.

The sixth pixel transistor T6 may include a gate electrode connected to the i-th emission control line EMLi, a first electrode connected to the third node N3, and a second electrode connected to a first electrode (e.g., an anode) of the light emitting element LED.

The seventh pixel transistor T7 may include a gate electrode connected to the i-1th scan line SLi-1, a first electrode to which the initialization signal VINT is applied, and a second electrode connected to the first electrode of the light emitting element LED.

The storage capacitor CST may include a first electrode to which the first power voltage ELVDD is applied and a second electrode connected to the first node N1.

The light emitting element LED may include the first electrode and a second electrode (e.g., a cathode) to which a second power supply voltage ELVSS is applied. The second power supply voltage ELVSS may be a low power supply voltage. The light emitting element LED may emit light based on a driving current provided from the pixel circuit PC. For example, the light emitting element LED may include an organic light emitting diode, an inorganic light emitting diode, a quantum dot light emitting diode, a micro light emitting diode, or the like.

FIG. 4 is illustrative, and the pixels PX may include a variety circuit structures. For example, the first to seventh pixel transistors T1, T2, T3, T4, T5, T6, and T7 are illustrated as p-channel metal oxide semiconductor (PMOS) transistors, however, the disclosure is not limited thereto. For example, the third pixel transistor T3 and the fourth pixel transistor T4 may be n-channel metal oxide semiconductor (NMOS) transistor. Or, for example, all of the first to seventh pixel transistors T1, T2, T3, T4, T5, T6, and T7 may be NMOS transistors.

In addition, the number of pixel transistors and the number of capacitors illustrated in FIG. 3 is only an example and may be variously changed according to embodiments.

FIG. 5 is a timing diagram illustrating an example in which the coupling occurs in a demux switching structure.

Referring to FIG. 5, in an embodiment, the first data signal of the second data signal from the data driver (e.g., the data driving chip DIC of FIG. 2) may output based on the first distribution selection signal (e.g., CLA of FIG. 5) and the second data distribution selection signal (e.g., CLB of FIG. 5) of the data distributor (e.g., the data distributor DXA of FIG. 2)).

For example, coupling between the first distribution selection signal and the second data distribution selection signal may occur.

For example, the CLA may output the green pixel data. The CLB may output the red and blue pixel data.

However, the disclosure is not limited thereto. For example, the CLA may output the red and blue pixel data. The CLB may output the green pixel data.

The color of data to be demuxed by the CLA may be G-G. For example, the data may be applied to the first data line DL1. For example, the color of the data to be demuxed by the CLB may be R-B. The data may be applied to a second data line DL2. For example, the color of the data to be demuxed at a first scan timing may be R, and the color of the data to be demuxed at a second timing may be G. However, the disclosure is not limited thereto.

A timing at which the gate signal is turned on (e.g., GW ON of FIG. 5) may be synchronized with a timing at which the CLA maintains a low level or a high level and a timing at which the CLB changed from a low level to a low level or from a low level to a high level.

As depicted in FIG. 5, the timing at which the gate signal is tuned on may include a first timing, and a second timing. Luminance of the green pixel (“G”) may become brighter due to the coupling at the first timing (see dot line). Accordingly, display quality may be deteriorated. For example, the image may become greenish.

However, this is illustrative and the disclosure is not limited thereto. For example, the disclosure may prevent a distortion of the coupling image quality by the first distribution selection signal and the second distribution selection signal.

In an embodiment, the display device 1000 according to embodiments of the disclosure may be grouped with data corresponding to the CLA and CLB. For example, as depicted in FIG. 3, the demuxed data by the CLA may be applied to the first data line DLI and the third data line DL3, and the demuxed data by the CLB may be applied to the second data line DL2 and the fourth data line DL4. Accordingly, the deterioration of the display quality due to the coupling may be prevented.

In addition, the data output path synchronized to the CLA and the data output path synchronized to the CLB may be spaced apart from each other. For example, as depicted in FIG. 3, the first power line PL1 may be disposed between the first data connection line groups (e.g., the first data line DL1 and the third data line DL3) and the second data connection line groups (e.g., the second data line DL2 and the fourth data line DL4). Accordingly, the deterioration of the display quality due to the coupling may be further prevented.

FIGS. 6, 7, 8, 9, 10, 11, and 12 are views illustrating the conductor line and the power line.

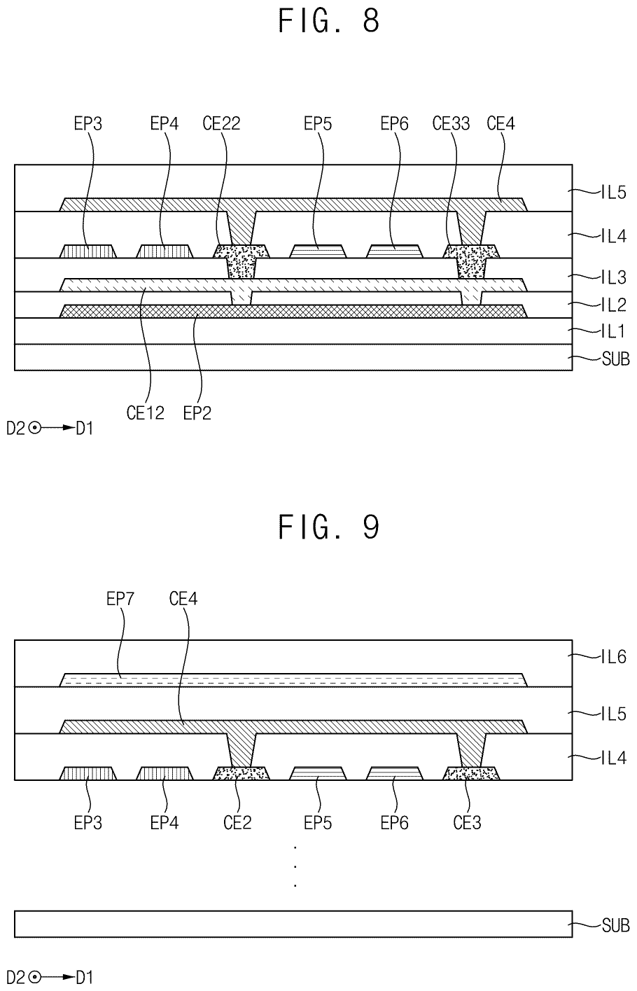

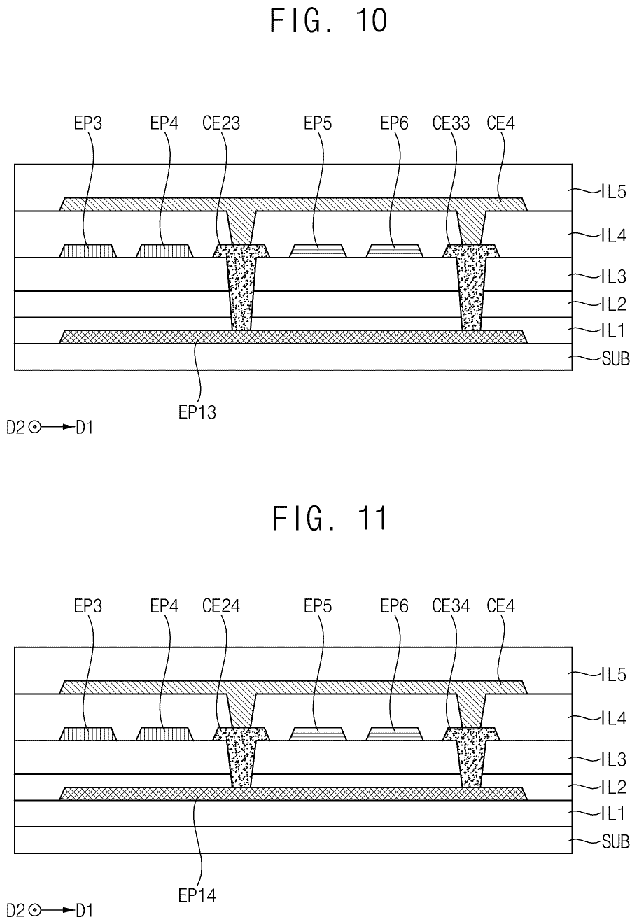

FIGS. 6, 7, and 8 are cross-sectional views of the display device according to a first embodiment of the disclosure cut along a I-I′ line of FIG. 3. FIG. 9 is a cross-sectional view of the display device according to a second embodiment of the disclosure cut along a I-I′ line of FIG. 3. FIG. 10 is a cross-sectional view of the display device according to a third embodiment of the disclosure cut along a I-I′ line of FIG. 3.

In an embodiment, in the cross-sectional view, each of the display devices according to the embodiments of the disclosure may include the substrate SUB, a plurality of electrodes and a plurality of insulating layers. For example, the plural insulating layers may insulate between the plurality of electrodes.

The substrate SUB may be an insulating substrate formed of a transparent or opaque material. For example, the substrate SUB may include plastic and be flexible.

In an embodiment, similar to described above with reference to FIG. 1, the substrate SUB may include the display area and the peripheral area adjacent to the display area. The peripheral area may include the first peripheral area, the bendable area, and the integrated circuit area positioned adjacent to the one direction from the display area.

Referring to FIG. 6, in the cross-sectional view, the display device according to the first embodiment of the disclosure may include a first pattern EP1, a first contact pattern CE1, a third pattern EP3, a fourth pattern EP4, a fifth pattern EP5, a sixth pattern EP6, a second contact pattern CE2, a third contact pattern CE3, a fourth contact pattern CE4, a first insulating layer IL1, a second insulating layer IL2, a third insulating layer IL3, a fourth insulating layer IL4, and a fifth insulating layer IL5, on the substrate SUB. For example, the first data connection line DCL1 and the third data connection line DCL3 included in the first data connection line groups of FIG. 3 may correspond to the third pattern EP3 and the fourth pattern EP4. The second data connection line DCL2 and the fourth data connection line DCL4 included in the second data connection line groups may correspond to the fifth pattern EP5 and the sixth pattern EP6. The first conductor line PL1 may correspond to the second contact pattern CE2. The second conductor line PL2 may correspond to the third contact pattern CE3.

Hereinafter, overlapping description of the display device (e.g., the display device 1000 of FIG. 2) described with reference to FIGS. 1, 2, 3, 4, and 5 will be omitted or simplified.

The first pattern EP1 may be disposed on the substrate SUB. For example, the first pattern EP1 may include oxide semiconductors, silicon semiconductors, organic semiconductors, or the like. For example, the oxide semiconductor may include at least one oxide of indium (“In”), gallium (“Ga”), tin (“Sn”), zirconium (“Zr”), vanadium (“V”), hafnium (“Hf”), cadmium (“Cd”), germanium (“Ge”), chromium (“Cr”), titanium (“Ti”) and zinc (“Zn”). The silicon semiconductor may include amorphous silicon, polycrystalline silicon, or the like.

In an embodiment, the first insulating layer IL1 covering the first pattern EP1 may be disposed on the substrate SUB. For example, the first insulating layer IL1 may include an inorganic insulating material.

The first contact pattern CE1 may be disposed on the first pattern EP1. The first contact pattern CE1 may penetrate the first insulating layer IL1 and contact with the first pattern EP1. For example, the first contact pattern CE1 may include a conductive material. For example, the conductive material may include a metal, an alloy, a conductive metal nitride, a conductive metal oxide, a transparent conductive material, or the like. For example, The first contact pattern CE1 may include molybdenum (“Mo”). However, the disclosure is not limited thereto.

In an embodiment, the second insulating layer IL2 covering the first contact pattern CE1 may be disposed on the first insulating layer IL1. The third insulating layer IL3 may be disposed on the second insulating layer IL2. For example, each of the second insulating layer IL2 and the third insulating layer IL3 may include an inorganic insulating material.

Each of the third pattern EP3, the fourth pattern EP4, the fifth pattern EP5, the sixth pattern EP6, the second contact pattern CE2, and the third contact pattern CE3 may be disposed on the first contact pattern CE1. For example, each of the third pattern EP3, the fourth pattern EP4, the fifth pattern EP5, the sixth pattern EP6, the second contact pattern CE2, and the third contact pattern CE3 may include a conductive material. For example, each of the third pattern EP3, the fourth pattern EP4, the fifth pattern EP5, the sixth pattern EP6, the second contact pattern CE2, and the third contact pattern CE3 may include aluminum (“Al”). However, the disclosure is not limited thereto.

In an embodiment, the first data connection line groups (e.g., the third pattern EP3 and the fourth pattern EP4), the second data connection line groups (e.g., the fifth pattern EP5 and the sixth pattern EP6), and the conductor lines (e.g., the second contact pattern CE2 and the third contact pattern CE3) may be positioned in the same layer.

In an embodiment, the conductor lines (e.g., the second contact pattern CE2 and the third contact pattern CE3) may penetrate the third insulating layer IL3 and the second insulating layer IL2 and contact the first contact pattern CE1.

In an embodiment, the conductor lines (e.g., the second contact pattern CE2 and the third contact pattern CE3) may be disposed between the first data connection line groups (e.g., the third pattern EP3 and the fourth pattern EP4) and the second data connection line groups (e.g., the fifth pattern EP5 and the sixth pattern EP6).

In an embodiment, the fourth insulating layer IL4 covering the first data connection line groups, the second data connection line groups, and conductor lines may be disposed on the third insulating layer IL3. For example, the fourth insulating layer IL4 may include an inorganic insulating material.

The fourth contact pattern CE4 may be disposed on the first data connection line groups, the second data connection line groups, and the conductor lines. In an embodiment, the first power voltage may be applied to the fourth contact pattern CE4. (Hereinafter, for the convenience of the description, the fourth contact pattern CE4 is also referred to as the fourth power line). In other words, in an embodiment, the fourth power line (i.e., the fourth contact pattern CE4) may be disposed on a layer different from the first data connection line groups (e.g., the third pattern EP3 and the fourth pattern EP4) and the second data connection line groups (e.g., the fifth pattern EP5 and the sixth pattern EP6), may be electrically connected to the conductor lines (e.g., the second contact pattern CE2 and the third contact pattern CE3) through a contact hole and provide the first power voltage.

In an embodiment, the fifth insulating layer IL5 covering the fourth power line (i.e., the fourth contact pattern CE4) may be disposed on the fourth insulating layer IL4. For example, the fifth insulating layer IL5 may include an organic insulating material.

In an embodiment, additional power line (e.g., the first pattern EP1 and the first contact pattern CE1) electrically connected to the conductor lines (e.g., the second contact pattern CE2 and the third contact pattern CE3) through a contact hole may further included, in a layer different from the fourth insulating layer IL4 and the fifth insulating layer IL5. In an embodiment, the additional line (e.g. the first pattern EP1 and the first contact pattern CE1) may be disposed under the fourth power line (e.g. the fourth contact pattern CE4).

The first supply voltage may be provided to the additional power line. In an embodiment, the additional power line may include a first power line (e.g., the first pattern EP1) and a second power line (e.g., the first contact pattern CE1). The first power line may be covered by the first insulating layer IL1. The second power line may be covered by the second insulating layer IL2, and may be electrically connected to the first power line and the conductor lines via the contact hole.

In an embodiment, in order to minimize line resistance, the additional power line may be formed in a large area.

In an embodiment, in the cross-sectional view, a width of the fourth power line (e.g., the fourth contact pattern CE4) may be greater than a width of each of the conductor lines (e.g., each of the second contact pattern CE2 and the third contact pattern CE3).

In an embodiment, the additional power line (e.g., the first pattern EP1 and the first contact pattern CE1) disposed under the fourth power line may include a first metal, and the fourth power line (e.g., the fourth contact pattern CE4) may include a second metal different from the first metal. In an embodiment, a resistivity of the second metal may be smaller than that of the first metal. For example, The first metal may include molybdenum (“Mo”), and the second metal may include aluminum (“Al”). However, the disclosure is not limited thereto.

In an embodiment, referring to FIG. 7, the display device according to the first embodiment may include the first pattern EP1, a first contact pattern CE11, the third pattern EP3, the fourth pattern EP4, the fifth pattern EP5, the sixth pattern EP6, a second contact pattern CE21, a third contact pattern CE31, the fourth contact pattern CE4, the first insulating layer IL1, the second insulating layer IL2, the third insulating layer IL3, the fourth insulating layer IL4, and the fifth insulating layer IL5, in the cross-sectional view.

The display device of FIG. 7 may differ from the display device of FIG. 6 in that the first pattern EP1 covered by the first insulating layer IL1 is contacted with the first contact pattern CE11 covered by the third insulating layer IL3.

In an embodiment, an additional power line may be disposed under the fourth power line (i.e., the fourth contact pattern CE4). In an embodiment, the additional power line may include the first power line (e.g., a first pattern EP1) and the third power line (e.g., the first contact pattern CE11). The first power line may be covered by the first insulating layer IL1. The third power line may be covered by the third insulating layer IL3. The third power line may be electrically connected by means of a contact hole with the first power line and the conductor lines (e.g., the second contact pattern CE21 and the third contact pattern CE31).

In an embodiment, in order to minimize the line resistance, the additional power line(s) may be formed in large area.

In an embodiment, the first power voltage may be provided to the additional power lines (e.g., the first pattern EP1 and the first contact pattern CE11).

In an embodiment, in the cross-sectional view, a width of the fourth power line (e.g., the fourth contact pattern CE4) may be greater than a width of each of the conductor lines (e.g., each of the second contact pattern CE21 and the third contact pattern CE31).

In an embodiment, the additional power lines (e.g., the first pattern EP1 and the first contact pattern CE11) disposed under the fourth power line may include a first metal, and the fourth power line (e.g., the fourth contact pattern CE4) may include a second metal different from the first metal. In an embodiment, a resistivity of the second metal may be smaller than that of the first metal.

In an embodiment, referring to FIG. 8, the display device according to the first embodiment of the disclosure may include a second pattern EP2, a first contact pattern CE12, the third pattern EP3, the fourth pattern EP4, the fifth pattern EP5, the sixth pattern EP6, a second contact pattern CE22, a third contact pattern CE33, the fourth contact pattern CE4, the first insulating layer IL1, the second insulating layer IL2, the third insulating layer IL3, the fourth insulating layer IL4, and the fifth insulating layer IL5, on the substrate SUB.

The display device of FIG. 8 may differ in that the second pattern EP2 covered by the second insulating layer IL2 is contacted with the first contact pattern CE12 covered by the third insulating layer IL3 of the display device of FIG. 6.

In an embodiment, an additional power line may be disposed under the fourth power line (i.e., the fourth contact pattern CE4). In an embodiment, the additional power line may include a second power line (e.g., a second pattern EP2) and a third power line (e.g., a first contact pattern CE12). The second power line may be covered by the second insulating layer IL2. The third power line may be covered by the third insulating layer IL3. The third power line may be electrically connected with the second power line and the conductor lines (e.g., the second contact pattern CE22 and the third contact pattern CE33) through a contact hole.

In an embodiment, in order to minimize the line resistance, the additional power line(s) may be formed in large area.

In an embodiment, the first power voltage may be provided to the additional power lines (e.g., the second pattern EP2 and the first contact pattern CE12).

In an embodiment, in the cross-sectional view, a width of the fourth power line (e.g., the fourth contact pattern CE4) may be greater than a width of each of the conductor lines (e.g., each of the second contact pattern CE22 and the third contact pattern CE33).

In an embodiment, the additional power line (e.g., the second pattern EP2 and the first contact pattern CE12) disposed under the fourth power line may include a first metal, and the fourth power line (e.g., the fourth contact pattern CE4) may include a second metal different from the first metal. In an embodiment, a resistivity of the second metal may be smaller than that of the first metal.

In an embodiment, referring to FIGS. 6 and 9, the display device according to the second embodiment of the disclosure may include the third pattern EP3, the fourth pattern EP4, the fifth pattern EP5, the sixth pattern EP6, the second contact pattern CE2, the third contact pattern CE3, the fourth contact pattern CE4, a seventh pattern EP7, the first insulating layer IL1, the second insulating layer IL2, the third insulating layer IL3, the fourth insulating layer IL4, the fifth insulating layer IL5, and a sixth insulating layer IL6. For convenience of explanation, the first to third insulating layers (IL1, IL2, and IL3) are omitted overlap with those of FIG. 6.

The display device of FIG. 9 may differ from the display device of FIG. 6 in that it further includes the seventh pattern EP7 disposed on the fourth contact pattern CE4.

In an embodiment, an additional power line may be further included on the fourth power line (e.g., the fourth contact pattern CE4). For example, a fifth power line (e.g., the seventh pattern EP7) may be disposed on the fourth power line. For example, the fifth power line may include a conduct material.

In an embodiment, the sixth insulating layer IL6 may be disposed on the fifth insulating layer IL5. The sixth insulating layer IL6 may cover the fifth power line. For example, the sixth insulating layer IL6 may include an organic insulating material.

In an embodiment, the first power voltage may be provided to the additional power line (e.g., the seventh pattern EP7).

In an embodiment, in the cross-sectional view, a width of the fourth power line (e.g., the fourth contact pattern CE4) may be greater than a width of each of the conductor lines (e.g., each of the second contact pattern CE2 and the third contact pattern CE3).

In an embodiment, the additional power line (e.g., the seventh pattern EP7) disposed on the fourth power line may include the first metal, and the additional power line (e.g., the first pattern EP1 of FIG. 6 or the first contact pattern CE1 of FIG. 6) disposed under the fourth power line (e.g., the fourth contact pattern CE4) may include a second metal different from the first metal. In an embodiment, a resistivity of the second metal may be greater than that of the first metal.

In an embodiment, in order to minimize the line resistance, the additional power line(s) may be formed in large area.

In an embodiment, the display device of the FIG. 9 may have a greater effect of reducing line resistance than the display device of FIGS. 6, 7, 8, and 9, but may use more masks. As the additional power line disposed on the fourth power line includes a metal with low resistivity (e.g., the first metal) than the additional line disposed under the fourth power line, the line resistance of the fourth power line may be more reduced than if it does not include the additional power line on the fourth power line.

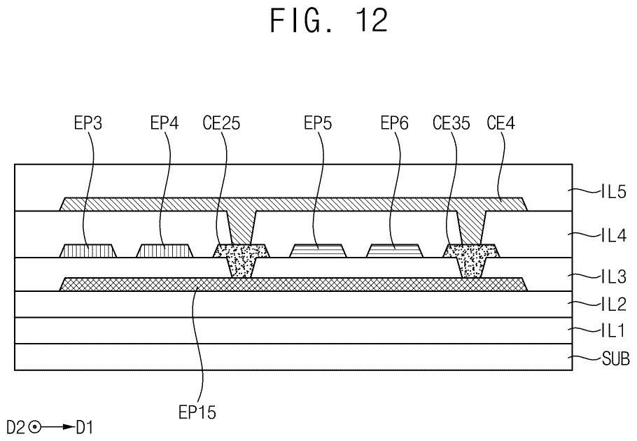

In an embodiment, referring to FIGS. 10, 11, and 12, the display device according to the third embodiment may include the first pattern (EP13 of FIG. 10, EP14 of FIG. 11, or EP15 of FIG. 12), the third pattern EP3, the fourth pattern EP4, the fifth pattern EP5, the sixth pattern EP6, the second contact pattern (CE23 of FIG. 10, CE24 of FIG. 11, or CE25 of FIG. 12), the third contact pattern (CE33 of FIG. 10, CE34 of FIG. 11, or CE35 of FIG. 12), the fourth contact pattern CE4, the first insulating layer IL1, the second insulating layer IL2, the third insulating layer IL3, the fourth insulating layer IL4, and the fifth insulating layer IL5, on the substrate SUB, in the cross-sectional view.

The display device of FIGS. 10, 11, and 12 may differ from the display device of FIG. 6 in that the first contact pattern CE1 disposed under the second contact pattern (CE2 of FIG. 6, CE23 of FIG. 10, CE24 of FIG. 11, or CE25 of FIG. 12) and the third contact pattern (CE3 of FIG. 6, CE33 of FIG. 10, CE34 of FIG. 11, or CE35 of FIG. 12) is omitted.

In an embodiment, as depicted in FIG. 10, the additional power line disposed under the fourth power line may be covered by the first insulating layer IL1, and a first power line (e.g., the first pattern EP13 electrically connected to the conductor lines (e.g., the second contact pattern CE23 and the third contact pattern CE33) through a contact hole may be included. However, the disclosure is not limited thereto.

In an embodiment, as depicted in FIG. 11, the additional power line may be covered by the second insulating layer IL2, and a second power line electrically connected to the conductor lines (e.g., the second contact pattern CE24 and the third contact pattern CE34) through a contact hole may be included.

In an embodiment, as depicted in FIG. 12, the additional power line may be covered by the third insulating layer IL3, and a third power line (e.g., the first pattern EP15) electrically connected to the conductor lines (e.g., the second contact pattern CE25 and the third contact pattern CE35) through a contact hole.

In an embodiment, in order to minimize the line resistance, the additional power line (e.g., the first pattern EP13 of FIG. 10, the first pattern of EP14 of FIG. 11) disposed under the fourth power line may be formed in a large area.

In an embodiment, the first power voltage may be provided to the additional power supply line (e.g., the first pattern EP13 of FIG. 10, the first pattern EP14 of FIG. 11, or the first pattern EP15 of FIG. 12).

In an embodiment, in the cross-sectional view, a width of the fourth power line (e.g., the fourth contact pattern CE4) may be greater than a width of each of the conductor lines (e.g., each of the second contact pattern (CE2 of FIG. 6, CE23 of FIG. 10, CE24 of FIG. 11, CE25 of FIG. 12) and the third contact pattern (CE of FIG. 6, CE33 of FIG. 10, CE34 of FIG. 11, or CE35 of FIG. 12).

In an embodiment, the additional power line (e.g., the first pattern EP13 of FIG. 10, the first pattern EP14 of FIG. 11, or the first pattern EP15 of FIG. 12) disposed under the fourth power line may include a first metal, and the fourth power line (e.g., the fourth contact pattern CE4) may include a second metal different from the first metal. In an embodiment, a resistivity of the second metal may be smaller than that of the first metal.

In an embodiment, the display device of FIGS. 10, 11, and 12 might not include the first contact pattern CE1 than the display device of FIGS. 6, 7, and 8. Accordingly, the less masks may be used in a manufacturing process of the display device, and the coupling effects between other lines (e.g. the data line) may be minimized.

As described above, in the display device according to embodiments of the disclosure, the conductor lines may be disposed between the data connection line groups (e.g. the first to second data connection line groups) branched from the data distributor DXA below the bendable area BA, and the additional power line (e.g., at least one of the first power line, the second power line, the third power line, or the fifth power line or combination therebetween) contact with the fourth power line with a large area may be disposed. Accordingly, the occurrence of the coupling between the CLA/CLB output signals may be prevented and the increase in resistance of the fourth power line may be minimized.

In addition, the additional power line (e.g., the first power line, the second power line, the third power line, or the fifth power line) may be disposed on/under the fourth power line. Accordingly, the occurrence of the coupling between the CLA/CLB output signals may be prevented and the increase in resistance of the fourth power line may be minimized. In addition, the resistivity of the metallic material included in the additional power line (e.g., the fifth power line) disposed on the conductor line may be smaller than the resistivity of the metallic material included in the additional power line (e.g., the first power line, the second power line, or the third power line) disposed under the conductor line. Accordingly, the increase in resistance of the power line may be further minimized.

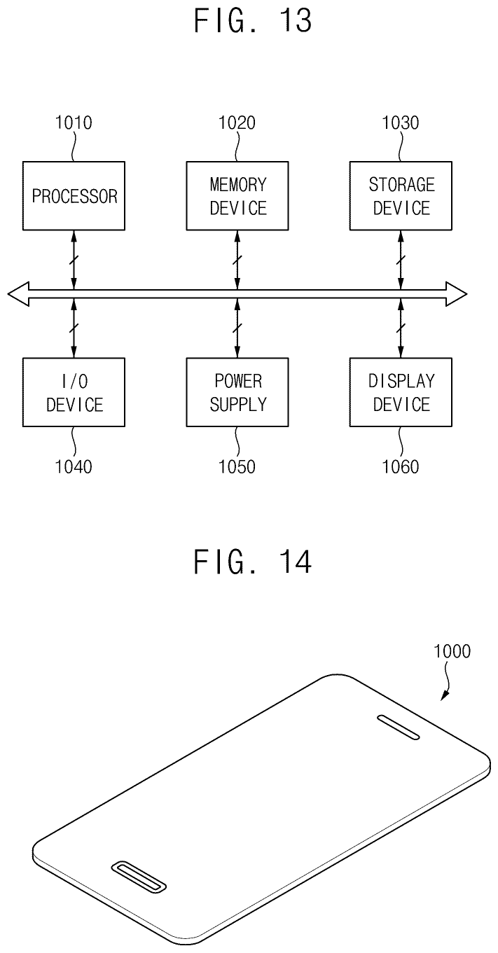

FIG. 13 is a block diagram illustrating an electronic apparatus according to an embodiment of the disclosure. FIG. 14 is a diagram illustrating an example in which the electronic apparatus of FIG. 13 is implemented as a smart phone.

Referring to FIGS. 13 and 14, the electronic apparatus may include the display device 1000 of FIG. 2. The electronic apparatus may include a processor 1010, a memory device 1020, a storage device 1030, an input/output (“I/O”) device 1040, a power supply 1050, and a display apparatus 1060. Here, the display apparatus 1060 may be the display device of FIGS. 1 and 2. In addition, the electronic apparatus may further include a plurality of ports for communicating with a video card, a sound card, a memory card, a universal serial bus (“USB”) device, other electronic apparatuses, etc.

In an embodiment, as depicted in FIG. 14, the electronic apparatus may be implemented as a smart phone. However, this is illustrative, and the electronic apparatus is not limited thereto. For example, the electronic apparatus may be implemented as a cellular phone, a video phone, a smart pad, a smart watch, a tablet PC, a car navigation system, a computer monitor, a laptop, a head mounted display (“HMD”) device, or the like.

The processor 1010 may be a micro-processor, a central processing unit (“CPU”), an application processor (“AP”), or the like. The processor 1010 may be coupled to other components via an address bus, a control bus, a data bus, or the like. Further, the processor 1010 may be coupled to an extended bus such as a peripheral component interconnection (“PCI”) bus.

The processor 1010 may output the input image data IMG and the input control signal CONT to the driving controller 200 of FIG. 1.

The memory device 1020 may store data for operations of the electronic apparatus. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like or at least one volatile memory device such as a dynamic random access memory (“DRAM”) device, a static random access memory (“SRAM”) device, a mobile dynamic random access memory device, or the like.

The storage device 1030 may include a solid state drive (“SSD”) device, a hard disk drive (“HDD”) device, a CD-ROM device, or the like. The I/O device 1040 may include an input device such as a keyboard, a keypad, a mouse device, a touch-pad, a touch-screen, or the like and an output device such as a printer, a speaker, or the like. In some embodiments, the display apparatus 1060 may be included in the I/O device 1040. The power supply 1050 may provide power for operations of the electronic apparatus 1000. The display apparatus 1060 may be coupled to other components via the buses or other communication links.

FIG. 15 is a view illustrating the bending state of the smartphone of FIG. 14.

Referring to FIGS. 2, 14, and 15, in an embodiment, the display device 1000 (e.g., the smartphone) may include the substrate SUB. In the bendable area BA of the substrate SUB, the bending line BL may be defined. The substrate SUB may be folded along the bending line BL.

In an embodiment, in the cross-sectional view, a circuit layer CL, a display element layer PXL, an input sensing layer ISP, an anti-reflective layer RPL, and a window WN may be disposed on the substrate SUB in a state where the substrate SUB is folded along the bending line BL.

The circuit layer CL may be disposed on the substrate SUB. For example, the circuit layer CL may include at least one insulating layer, drive elements, signal lines, and signal pads. To this end, patterns and semiconductor patterns may be disposed in the circuit layer CL. Form the insulating layer, semiconductor layer, and conductor layer, and form the insulating layer, the drive elements, the signal lines, and the signal pads by patterning process.

The display element layer PXL may be disposed on the circuit layer CL. The display element layer PXL may include a plurality of pixels (e.g., the pixels PX of FIG. 1) that are disposed overlapping with the display area AA. Each of the plurality of pixels may be electrically connected to the drive elements and may output light according to the signal of the drive element.

Accordingly, a display panel including the circuit layer CL and the display element layer PXL disposed sequentially on the substrate SUB may be formed.

The input sensing layer ISP may be disposed on the display panel. The input sensing layer ISP may be disposed on the display panel without an additional adhesive member. However, the disclosure is not limited thereto. After forming the input sensing layer ISP separately, and the input sensing layer ISP may be attached on the display panel using an adhesive member.

The input sensing layer ISP may detect an external input applied from the outside of the display device 1000 and acquire a coordinate information of the external input. For example, the input sensing layer ISP may be driven in a variety of ways, including capacitive, resistive, infrared, pressure, or the like. However, the disclosure is not limited thereto.

The anti-reflective layer RPL may be disposed on the input sensing layer ISP. The anti-reflective layer RPL may be disposed on the input sensing layer ISP without an additional adhesive member. However, the disclosure is not limited thereto. After forming the anti-reflective layer RPL separately, the anti-reflective layer RPL may be attached on the input sensing layer ISP using an adhesive member.

The anti-reflective layer RPL may reduce a reflectivity of an incident outside light from an upper side of the display device 1000. For example, the anti-reflective layer RPL may include a phase retarder, polarizer, and color filter. These may be used alone or in combination with each other. However, the disclosure is not limited thereto.

Accordingly, a display module including the input sensing layer ISP and the anti-reflective layer RPL disposed sequentially on the display panel may be formed.

The window WN may be disposed on the display module. The window WN may cover the display module to protect the display module from external shocks. For example, the window WN may include glass, sapphire, polymers, or the like. These may be used alone or in combination with each other.

In an embodiment, in the side-view, in the state where the substrate SUB is folded along the bending line BL, the data distributor DXA, the data driver (e.g., the driving chip DIC of FIG. 2), a bending protective layer BPL, and a lower member CSL may be disposed under the substrate SUB.

The bending protective layer BPL may be disposed in a position corresponding to the bendable area BA. Accordingly, when the display device 1000 is bent, a tensile stress may be relieved to protect the bendable area BA.

The lower member CSL may be disposed on the back surface of the display panel. The lower member CSL may include a buffering material. For example, the buffering material may include sponges, foam, urethane resin, flexible polymer materials, or the like. These may be used alone or in combination with each other. The lower member CSL may protect the back surface of the display panel from external shocks.

However, FIG. 15 is illustrative, and the components of the display device 1000 may be variously changed (substitution, omission).

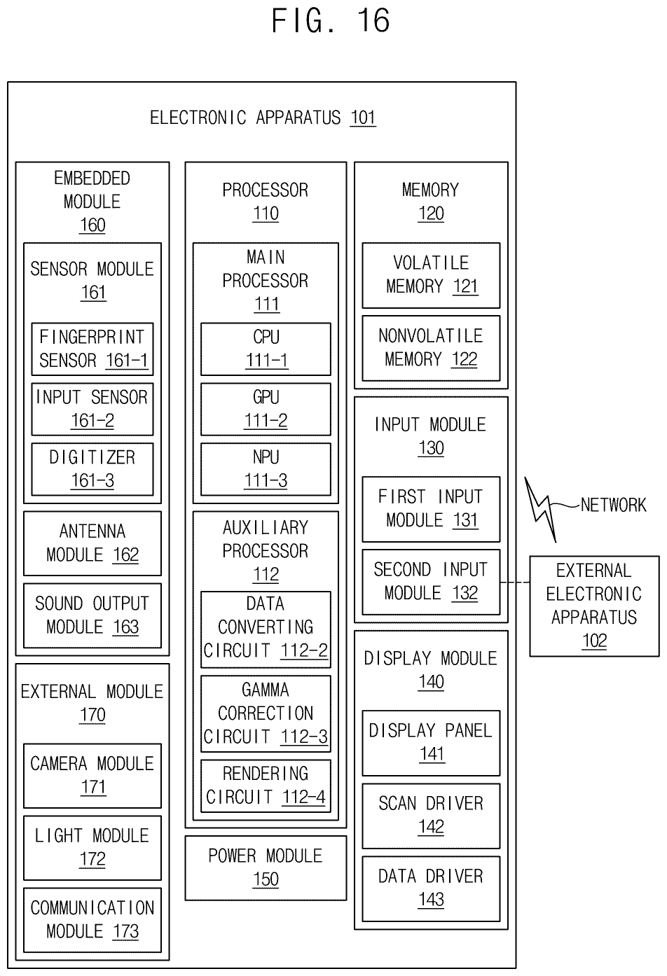

FIG. 16 is a block diagram illustrating an electronic apparatus according to an embodiment of the disclosure.

Referring to FIG. 16, an electronic apparatus 101 outputs various information through a display module 140 in an operating system. When a processor 110 executes an application stored in a memory 120, the display module 140 provides application information to a user through a display panel 141.

The processor 110 obtains an external input through an input module 130 or a sensor module 161 and executes an application corresponding to the external input. For example, when the user selects a camera icon displayed on the display panel 141, the processor 110 obtains a user input through an input sensor 161-2 and activates a camera module 171. The processor 110 transfers image data corresponding to a captured image obtained through the camera module 171 to the display module 140. The display module 140 may display an image corresponding to the captured image through the display panel 141.

In an embodiment, when a personal information authentication is executed in the display module 140, a fingerprint sensor 161-1 obtains input fingerprint information as input data. The processor 110 compares input data obtained through the fingerprint sensor 161-1 with authentication data stored in the memory 120, and executes an application according to a comparison result. The display module 140 may display information executed according to application logic through the display panel 141.

In an embodiment, when a music streaming icon displayed on the display module 140 is selected, the processor 110 obtains a user input through the input sensor 161-2 and activates a music streaming application stored in the memory 120. When a music execution command is input in the music streaming application, the processor 110 activates a sound output module 163 to provide sound information corresponding to the music execution command to the user.

In the above, the operation of the electronic apparatus 101 is briefly described. Hereinafter, a configuration of the electronic apparatus 101 is described in detail. Some of elements of the electronic apparatus 101 described later may be integrated and provided as one element, or one element may be separated as two or more elements.

The electronic apparatus 101 may communicate with an external electronic apparatus 102 through a network (e.g. a short-range wireless communication network or a long-range wireless communication network). According to an embodiment, the electronic apparatus 101 may include the processor 110, the memory 120, the input module 130, the display module 140, a power module 150, an embedded module 160, and an external module 170. According to an embodiment, in the electronic apparatus 101, at least one of the above-described elements may be omitted or one or more other apparatus may be added. According to an embodiment, some of the above-described elements (e.g., the sensor module 161, an antenna module 162 or the sound output module 163) may be integrated into another element (e.g. the display module 140).

The processor 110 may execute software to control at least one other element (e.g. hardware or software element) of the electronic apparatus 101 connected to the processor 110 and to perform various data processing or operations. According to an embodiment, as at least part of the data processing or the operations, the processor 110 may store receive instructions or data from other elements (e.g. the input module 130, the sensor module 161 or a communication module 173) in a volatile memory 121, may process the instructions or data stored in the volatile memory 121 and may store result data of the processing in a nonvolatile memory 122.

The processor 110 may include a main processor 111 and an auxiliary processor 112. The main processor 111 may include at least one of a central processing unit (“CPU”) 111-1 and an application processor (“AP”). The main processor 111 may further include any one or more of a graphic processing unit (“GPU”) 111-2, a communication processor (“CP”) and an image signal processor (“ISP”). The main processor 111 may further include a neural processing unit (“NPU”) 111-3. The neural network processing unit 111-3 is a processor specialized in processing an artificial intelligence model. The artificial intelligence model may be generated through a machine learning. The artificial intelligence model may include a plurality of artificial neural network layers. The artificial neural network may be one of a deep neural network (“DNN”), a convolutional neural network (“CNN”), a recurrent neural network (“RNN”), a restricted boltzmann machine (“RBM”), a deep belief network (“DBN”), a bidirectional recurrent deep neural network (“BRDNN”) and a deep Q-networks or a combination of two or more of the above. However, the artificial neural network is not limited to the above examples. The artificial intelligence model may include software structures, in addition to hardware structures or instead of the hardware structures. At least two of the above-described processing units and the above-described processors may be implemented as an integrated element (e.g. a single chip) or each may be implemented as independent elements (e.g. in a plurality of chips).

The auxiliary processor 112 may include a controller. The controller may include an interface conversion circuit and a timing control circuit. The controller receives an image signal from the main processor 111, converts a data format of the image signal to meet interface specifications with the display module 140, and outputs image data. The controller may output various control signals for driving the display module 140.

The auxiliary processor 112 may further include a data converting circuit 112-2, a gamma correction circuit 112-3 and a rendering circuit 112-4. The data converting circuit 112-2 may receive the image data from the controller and may compensate the image data such that the image is displayed with a desired luminance according to characteristics of the electronic apparatus 101 or a user setting or may convert the image data to reduce a power consumption or compensate for afterimages. The gamma correction circuit 112-3 may convert the image data or a gamma reference voltage such that the image displayed on the electronic apparatus 101 has desired gamma characteristics. The rendering circuit 112-4 may receive the image data from the controller and may render the image data based on a pixel arrangement of the display panel 141 included in the electronic apparatus 101. At least one of the data converting circuit 112-2, the gamma correction circuit 112-3 and the rendering circuit 112-4 may be integrated into another element (e.g. the main processor 111 or the controller). At least one of the data converting circuit 112-2, the gamma correction circuit 112-3 and the rendering circuit 112-4 may be integrated into a data driver 143 to be described later.

The memory 120 may store various data used by at least one element (e.g. the processor 110 or the sensor module 161) of the electronic apparatus 101 and input data or output data for commands related thereto. The memory 120 may include at least one of the volatile memory 121 and the nonvolatile memory 122.

The input module 130 may receive commands or data used to the elements (e.g. the processor 110, the sensor module 161 or the sound output module 163) of the electronic apparatus 101 from the outside of the electronic apparatus 101 (e.g. the user or the external electronic apparatus 102).

The input module 130 may include a first input module 131 for receiving commands or data from the user and a second input module 132 for receiving commands or data from the external electronic apparatus 102. The first input module 131 may include a microphone, a mouse, a keyboard, a key (e.g. a button) or a pen (e.g. a passive pen or an active pen). The second input module 132 may support a designated protocol capable of connecting to the external electronic apparatus 102 by wire or wirelessly. According to an embodiment, the second input module 132 may include a high definition multimedia interface (“HDMI”), a universal serial bus (“USB”) interface, an “SD card interface or an audio interface. The second input module 132 may include a connector physically connected to the external electronic apparatus 102, for example, an HDMI connector, a USB connector, an SD card connector, or an audio connector (e.g. a headphone connector).

The display module 140 visually provides information to the user. The display module 140 may include the display panel 141, a scan driver 142 and the data driver 143. The display module 140 may further include a window, a chassis and a bracket to protect the display panel 141.

The display panel 141 may include a liquid crystal display panel, an organic light emitting display panel or an inorganic light emitting display panel. A type of the display panel 141 is not particularly limited. The display panel 141 may be a rigid type or a flexible type capable of being rolled or folded. The display module 140 may further include a supporter or a heat dissipation member supporting the display panel 141.

The scan driver 142 may be mounted on the display panel 141 as a driving chip. Alternatively, the scan driver 142 may be integrated on the display panel 141. For example, the scan driver 142 may include an amorphous silicon TFT gate driver circuit (“ASG”) integrated on the display panel 141, a low temperature polycrystalline silicon (“LTPS”) TFT gate driver circuit integrated on the display panel 141, or an oxide semiconductor TFT gate driver circuit (“OSG”) integrated on the display panel 141. The scan driver 142 receives a control signal from the controller and outputs the scan signals to the display panel 141 in response to the control signal.

The display module 140 may further include a light emission driver. The light emission driver outputs a light emission control signal to the display panel 141 in response to a control signal received from the controller. The light emission driver may be formed independently from the scan driver 142. Alternatively, the light emission driver and the scan driver 142 may be integrally formed.

The data driver 143 receives a control signal from the controller and converts the image data into an analog voltage (e.g. the data voltage) and output the data voltages to the display panel 141 in response to the control signal.

The data driver 143 may be integrated into another element (e.g. the controller). The functions of the interface conversion circuit and the timing control circuit of the controller described above may be integrated into the data driver 143.

The display module 140 may further include a voltage generating circuit. The voltage generating circuit may output various voltages for driving the display panel 141.

The power module 150 supplies power to elements of the electronic apparatus 101. The power module 150 may include a battery which supplies a power voltage. The battery may include a non-rechargeable primary cell, a rechargeable secondary cell or a fuel cell. The power module 150 may include a power management integrated circuit (“PMIC”). The PMIC supplies optimized power to each of the above-described modules and modules described later. The power module 150 may include a wireless power transmission/reception member electrically connected to the battery. The wireless power transmission/reception member may include a plurality of antenna radiators in a form of coils.

The electronic apparatus 101 may further include the embedded module 160 and the external module 170. The embedded module 160 may include the sensor module 161, the antenna module 162 and the sound output module 163. The external module 170 may include the camera module 171, a light module 172 and the communication module 173.

The sensor module 161 may detect an input by a user's body or an input by the pen among the first input module 131, and generate an electrical signal or data value corresponding to the input. The sensor module 161 may include at least one of the fingerprint sensor 161-1, the input sensor 161-2 and a digitizer 161-3.

The fingerprint sensor 161-1 may generate a data value corresponding to a user's fingerprint. The fingerprint sensor 161-1 may include one of an optical fingerprint sensor or a capacitive fingerprint sensor.

The input sensor 161-2 may generate data values corresponding to coordinate information of the input by the user's body or the input by the pen. The input sensor 161-2 generates a capacitance change due to an input as a data value. The input sensor 161-2 may detect an input by the passive pen or transmit/receive data to/from the active pen.

The input sensor 161-2 may measure bio-signals such as a blood pressure, a moisture, or a body fat. For example, when a user touches a part of his body to a sensor layer or a sensing panel and does not move for a certain period of time, the input sensor 161-2 may detect the bio-signal based on a change in an electric field caused by the part of the body so that the display module 140 may output user's desired information.

The digitizer 161-3 may generate a data value corresponding to the coordinate information input by the pen. The digitizer 161-3 generates an amount of electromagnetic change by the input as a data value. The digitizer 161-3 may detect an input by the passive pen or transmit/receive data to/from the active pen.

At least one of the fingerprint sensor 161-1, the input sensor 161-2 and the digitizer 161-3 may be formed as a sensor layer on the display panel 141 through a continuous process. The fingerprint sensor 161-1, the input sensor 161-2 and the digitizer 161-3 may be disposed on the display panel 141. At least one of the fingerprint sensor 161-1, the input sensor 161-2 and the digitizer 161-3, for example, the digitizer 161-3, may be disposed under the display panel 141.

At least two or more of the fingerprint sensor 161-1, the input sensor 161-2 and the digitizer 161-3 may be integrated into the sensing panel through the same process. When at least two or more of the fingerprint sensor 161-1, the input sensor 161-2 and the digitizer 161-3 are integrated into the sensing panel, the sensing panel may be disposed between the display panel 141 and a window disposed over an upper surface of the display panel 141. According to an embodiment, the sensing panel may be disposed on the window. The present inventive concept may not be limited to a position of the sensing panel.

At least one of the fingerprint sensor 161-1, the input sensor 161-2 and the digitizer 161-3 may be embedded in the display panel 141. For example, at least one of the fingerprint sensor 161-1, the input sensor 161-2 and the digitizer 161-3 is formed simultaneously with the display panel 141 through a process of forming elements included in the display panel 141 (e.g. light emitting elements, transistors, etc.).

In addition, the sensor module 161 may generate an electrical signal or a data value corresponding to an internal state or an external state of the electronic apparatus 101. For example, the sensor module 161 may further include a gesture sensor, a gyro sensor, a barometric pressure sensor, a magnetic sensor, an acceleration sensor, a grip sensor, a proximity sensor, a color sensor, an infrared (“IR”) sensor, a biosensor, a temperature sensor, a humidity sensor or an illuminance sensor.

The antenna module 162 may include one or more antennas for transmitting a signal or power to outside or receiving a signal or power from outside. According to an embodiment, the communication module 173 may transmit a signal to an external electronic apparatus or receive a signal from an external electronic apparatus through an antenna suitable for a communication method. An antenna pattern of the antenna module 162 may be integrated with an element of the display module 140 (e.g. the display panel 141) or the input sensor 161-2.

The sound output module 163 is a device for outputting sound signals to the outside of the electronic apparatus 101. For example, the sound output module 163 may include a speaker used for general purposes such as playing multimedia or recording and a receiver used exclusively for receiving a call. According to an embodiment, the receiver may be formed integrally with or separately from the speaker. A sound output pattern of the sound output module 163 may be integrated with the display module 140.

The camera module 171 may capture still images and moving images. According to an embodiment, the camera module 171 may include one or more lenses, an image sensor or an image signal processor. The camera module 171 may further include an infrared camera capable of determining a presence or an absence of a user, the user's location and the user's gaze.

The light module 172 may provide a light. The light module 172 may include a light emitting diode or a xenon lamp. The light module 172 may operate in conjunction with the camera module 171 or operate independently.

The communication module 173 may support establishment of a wired or wireless communication channel between the electronic apparatus 101 and the external electronic apparatus 102 and communication through the established communication channel. The communication module 173 may include one or both of a wireless communication module such as a cellular communication module, a short-distance wireless communication module, or a global navigation satellite system (“GNSS”) communication module and a wired communication module such as a local area network (“LAN”) communication module, or a power line communication module. The communication module 173 may communicate with the external electronic apparatus 102 through a short-range communication network such as Bluetooth, Wi-Fi direct or infrared data association (“IrDA”) or a long-distance communication network such as a cellular network, the Internet, or a computer network (e.g. “LAN” or “WAN”). The various types of communication modules 173 described above may be implemented as a single chip or may be implemented as separate chips.

The input module 130, the sensor module 161 and the camera module 171 may be used to control the operation of the display module 140 in conjunction with the processor 110.

The processor 110 outputs commands or data to the display module 140, the sound output module 163, the camera module 171 or the light module 172 based on the input data received from the input module 130. For example, the processor 110 may generate image data corresponding to input data applied through a mouse or an active pen, and output the generated image data to the display module 140 or the processor 110 may generate command data corresponding to the input data and output the generated command data to the camera module 171 or the light module 172. When input data is not received from the input module 130 for a certain period of time, the processor 110 converts an operation mode of the electronic apparatus 101 into a low power mode or a sleep mode so that a power consumption of the electronic apparatus 101 may be reduced.

The processor 110 outputs commands or data to the display module 140, the sound output module 163, the camera module 171 or the light module 172 based on sensed data received from the sensor module 161. For example, the processor 110 may compare authentication data applied by the fingerprint sensor 161-1 with authentication data stored in the memory 120, and then execute an application according to the comparison result. The processor 110 may execute commands or output corresponding image data to the display module 140 based on the sensed data sensed by the input sensor 161-2 or the digitizer 161-3. When the sensor module 161 includes a temperature sensor, the processor 110 may receive temperature data for the temperature measured from the sensor module 161 and may further perform luminance correction on the image data based on the temperature data.

The processor 110 may receive determined data about the presence or the absence of the user, the user's location and the user's gaze from the camera module 171. The processor 110 may further perform luminance correction on the image data based on the determined data. For example, the processor 110, which determines the presence or the absence of the user through an input from the camera module 171, may display image data having the luminance corrected by the data converting circuit 112-2 or the gamma correction circuit 112-3 to the display module 140.

Some of the above elements may be connected to each other through a communication method between peripheral devices such as a bus, a general purpose input/output (“GPIO”), a serial peripheral interface (“SPI”), a mobile industry processor interface (MIPI), or an ultra-path interconnect (“UPI”) link to exchange signals (e.g. commands or data) with each other. The processor 110 may communicate with the display module 140 through an agreed interface. For example, the processor 110 may communicate with the display module 140 through any one of the above communication methods. The disclosure may not be limited to the above communication methods.

The electronic apparatus 101 according to various embodiments disclosed in the disclosure may be various types of apparatuses. For example, the electronic apparatus 101 may include at least one of a portable communication apparatus (e.g. a smart phone), a computer apparatus, a portable multimedia apparatus, a portable medical apparatus, a camera, a wearable device and a home appliance. The electronic apparatus 101 according to the embodiment of the disclosure may not be limited to the aforementioned apparatuses.

In an embodiment, the display panel 100 of FIG. 1 may correspond to the display panel 141 of FIG. 16. For example, the driving controller 200 of FIG. 1 may correspond to the controller of the auxiliary processor 112 of FIG. 16. For example, the gate driver 300 of FIG. 1 may correspond to the scan driver 142 of FIG. 16. For example, the data driver 500 of FIG. 1 may correspond to the data driver 143 of FIG. 16.

The present disclosure may be applied in manufacturing any of computer, notebook, cell phone, smart pad, PMP, PDA, MP3 player or the like.

Although embodiments have been described with reference to the drawings, the illustrated embodiments are provided as examples, and may be modified and changed by a person having ordinary knowledge in the relevant technical field without departing from the technical spirit set forth in the following claims.

What is claimed is:

1. A display device comprising:
a substrate including a display area and a peripheral area, the peripheral area including a first peripheral area positioned in a direction away from the display area, an integrated circuit area spaced apart from the first peripheral area, and a bendable area positioned between the first peripheral area and the integrated circuit area;
a data driver disposed in the integrated circuit area on the substrate;
a data distributor positioned between the integrated circuit area and the bendable area on the substrate;
first data connection line groups electrically connected to the data distributor and configured to receive a first data signal output from the data driver in response to a first distribution selection signal;
second data connection line groups electrically connected to the data distributor and configured to receive a second data signal output from the data driver in response to a second distribution selection signal;
conductor lines positioned between the first data connection line groups and the second data connection line groups; and
a fourth power line disposed on a different layer from the first data connection line groups and the second data connection line groups in a cross-sectional view and electrically connected to the conductor lines through a contact hole to provide a first power voltage to the conductor lines.

2. The display device of claim 1, wherein the first data connection line groups, the second data connection line groups, and the conductor lines are positioned on a same layer.

3. The display device of claim 1, in the cross-sectional view, further comprising:
a first insulating layer disposed on the substrate;
a second insulating layer disposed on first insulating layer;
a third insulating layer disposed on the second insulating layer;
a fourth insulating layer disposed on the third insulating layer; and
a fifth insulating layer disposed on the fourth insulating layer, and
wherein the first data connection line groups, the second data connection line groups, and the conductor lines are covered by the fourth insulating layer, and
wherein the fourth power line is covered by the fifth insulating layer.

4. The display device of claim 3, wherein a width of the fourth power line is greater than a width of each of the conductor lines, in the cross-sectional view.

5. The display device of claim 4, further comprising:
an additional power line electrically connected to the conductor lines through a contact hole in a layer different from the fourth insulating layer and the fifth insulating layer, in the cross-sectional view.

6. The display device of claim 5, wherein a width of the additional power line is greater than a width of each of the conductor lines.

7. The display device of claim 5,
wherein the additional power line comprises:
a first power line covered by the first insulating layer; and
a second power line covered by the second insulating layer, and electrically connected to the first power line and the conductor lines through a contact hole.

8. The display device of claim 5, further comprising:
a sixth insulating layer disposed on the fifth insulating layer; and
a fifth power line covered by the sixth insulating layer.

9. The display device of claim 5,
wherein the additional power line includes at least one of a first power line covered by the first insulating layer and electrically connected to the conductor lines through a contact hole, a second power line covered by the second insulating layer and electrically connected to the conductor lines through a contact hole, a third power line covered by the third insulating layer and electrically connected to the conductor lines through a contact hole.

10. The display device of claim 5, wherein, in the cross-sectional view,
the additional power line disposed under the fourth insulating layer includes a first metal, and
the additional power line disposed on the fourth insulating layer includes a second metal different from the first metal.

11. The display device of claim 10, wherein a resistivity of the second metal is smaller than a resistivity of the first metal.

12. The display device of claim 1, wherein the first data connection line groups, the second data connection line groups, and the conductor lines are spaced apart from each other in a direction crossing the one direction, in the cross-sectional view.

13. The display device of claim 1, wherein,
a bending line on which the substrate is folded is defined in the bendable area, and
when viewed from a side, with the substrate folded along the bending line, a pixel is disposed in the display area on the substrate, and the data distributor and the data driver are positioned under the substrate.

14. A display device comprising:
a substrate including a display area and a peripheral area, the peripheral area including a first peripheral area positioned in a direction away from the display area, an integrated circuit area spaced apart from the first peripheral area, and a bendable area positioned between the first peripheral area and the integrated circuit area;
a data driver disposed in the integrated circuit area on the substrate;
a data distributor positioned between the integrated circuit area and the bendable area on the substrate;
first data connection line groups electrically connected to the data distributor and configured to receive a first data signal output from the data driver in response to a first distribution selection signal;
second data connection line groups electrically connected to the data distributor and configured to receive a second data signal output from the data driver in response to a second distribution selection signal;
conductor lines positioned between the first data connection line groups and the second data connection line groups and configured to receive a first power voltage; and
a fourth power line disposed on the first data connection line groups and the second data connection line groups in a cross-sectional view, and having a width greater than a width of each of the conductor lines.

15. The display device of claim 14, further comprising:
an additional power line disposed under the conductor lines in the cross-sectional view, and electrically connected to the conductor lines through a contact hole.

16. The display device of claim 15, further comprising:
an additional power line disposed on the fourth power line in the cross-sectional view, and electrically connected to the conductor lines through a contact hole.

17. The display device of claim 16,
wherein, in the cross-sectional view, the additional power line disposed under the conductor lines includes a first metal, and
the additional power line disposed on the fourth insulating layer includes a second metal which resistivity is smaller than a resistivity of the first metal.

18. An electronic apparatus comprising:
a power module which supplies a power; and
a display device which provides the power from the power module, and
the display device comprises:
a substrate including a display area and a peripheral area, the peripheral area including a first peripheral area positioned in a direction away from the display area, an integrated circuit area spaced apart from the first peripheral area, and a bendable area positioned between the first peripheral area and the integrated circuit area;
a data driver disposed in the integrated circuit area on the substrate;
a data distributor positioned between the integrated circuit area and the bendable area on the substrate;
first data connection line groups electrically connected to the data distributor and configured to receive a first data signal output from the data driver in response to a first distribution selection signal;
second data connection line groups electrically connected to the data distributor and configured to receive a second data signal output from the data driver in response to a second distribution selection signal;
conductor lines positioned between the first data connection line groups and the second data connection line groups and configured to receive a first power voltage; and
a fourth power line disposed on the first data connection line groups and the second data connection line groups in a cross-sectional view, and having a width greater than a width of each of the conductor lines.

19. The display device of claim 18, further comprising:
an additional power line disposed under the conductor lines in the cross-sectional view, and electrically connected to the conductor lines through a contact hole.

20. The display device of claim 19, further comprising:
an additional power line disposed on the fourth power line in the cross-sectional view, and electrically connected to the conductor lines through a contact hole.
